(19) United States
(12) Patent Application Publication
(10) Pub. No.: US 2025/0081853 A1
(43) Pub. Date: Mar. 6, 2025

(54) COMPOSITE MATERIAL WITH PIEZOELECTRIC PROPERTIES, PRODUCTION PROCESS AND ELECTRONIC COMPONENT COMPRISING THE COMPOSITE MATERIAL

(71) Applicant: STMicroelectronics International N.V., Geneva (CH)

(72) Inventors: Christian VERRENGIA CAPOROSSI, Giugliano in Campania (IT); Annachiara ESPOSITO, Napoli (IT); Paola Sabrina BARBATO, Pozzuoli (IT); Valeria CASUSCELLI, Napoli (IT); Rossana SCALDAFERRI, Vibonati (IT)

(73) Assignee: STMicroelectronics International N.V., Geneva (CH)

(21) Appl. No.: 18/819,799

(22) Filed: Aug. 29, 2024

(30) Foreign Application Priority Data
Sep. 1, 2023 (IT) 102023000018027

(51) Int. Cl. H10N 30/85; C08K 3/22; C09D 5/24; C09D 7/40; C09D 7/61; C09D 127/16; H04R 17/02; H10N 30/092

(52) U.S. Cl. CPC H10N 30/852; C09D 5/24; C09D 7/61; C09D 7/67; C09D 127/16; H10N 30/092; C08K 2003/2244; C08K 2201/001; C08K 2201/011; H04R 17/025; H04R 2201/003

(57) ABSTRACT

Composite material comprising a fluoropolymer matrix and a filler formed of nanoparticles of a ceramic of the BZT-αBXT type wherein X is selected from Ca, Sn, and Mn and a is a molar fraction selected in the range between 0.10-0.90 doped with at least one doping element selected from the group consisting of Nb, La, Mn, Nd and W, wherein when X is Mn, the doping element is not Mn, wherein said nanoparticles have an average diameter comprised between 10 and 25% by weight on the total weight of the composite. The composite material is used to form a thin film usable as a piezoelectric material with inductive properties in electronic components, for example acoustic sensors such as microphones, and energy harvesting transducers.

### BACKGROUND

### Technical Field

The present disclosure relates to a composite material with piezoelectric properties, to a process for producing a thin film comprising the composite material and to the electronic component comprising the composite material. The electronic component may be for example a microelectromechanical (MEMS) device such as an acoustic sensor or actuator, in particular a microphone.

### Description of the Related Art

Significant progress has recently been made in the development of innovative materials for piezoelectric and acoustoelectric conversion. Acoustoelectric conversion has numerous applications, for example, for sound detection and recording, speed measurement, human activity detection, entertainment, information recognition, elderly care and security.

Acoustoelectric conversion may also be used for small-scale energy harvesting and powering. In fact, acoustoelectric conversion converts acoustic waves into electrical signals and may be obtained by exploiting several phenomena such as, for example, the piezoelectric effect.

Piezoelectric acoustoelectric conversion, based on the deformation of a material caused by the vibrations of acoustic waves, is particularly suitable for developing flexible devices.

Conventionally, piezoelectric films are used to manufacture acoustoelectric transducers. In this context, recently, piezoelectric polymers have aroused particular interest, such as, for example, polyvinylidene fluoride (PVDF) and its copolymers, or composites based on a piezoelectric polymeric matrix that have shown acoustoelectric transduction capabilities.

These materials are particularly advantageous as, compared to piezoelectric ceramics, they have excellent flexibility.

It is generally recognized that PVDF, as a semicrystalline polymer, has five polymorphs: α, β, γ, δ and ε. The piezoelectric property of PVDF is attributed to the existence of polar crystalline phases, including the β-and γ-phase, and the β-phase shows the greatest electric dipole moment among all crystalline phases of the polymer. Therefore, one of the strategies to improve the piezoelectric performances of PVDF-based sensors, actuators and energy harvesting transducers has been that of increasing the β-phase content.

Although the piezoelectric coefficient of PVDF and its copolymers is not as high as that of inorganic piezoelectric materials, their good flexibility, strength, chemical resistance, and biocompatibility make them promising piezoelectric candidates for self-powered sensors, microphones, and energy harvesting transducers.

PVDF-based composites containing piezoelectric ceramic fibers have also been prepared over the years in order to optimize PVDF-based devices and to obtain higher sensitivity and higher output power, thus laying the foundation for various applications, for example, in the wearable devices and implants sectors.

On the other hand, the materials currently available (for example aluminum nitride, AlN) have a long and complex production process, which may envisage over thirty deposition steps to form layers of useful thickness in commercial applications.

New piezoelectric materials with improved performances and easy production are therefore being sought.

### BRIEF SUMMARY

The present disclosure provides a new material with improved piezoelectric and ferroelectric properties which overcomes the drawbacks of the prior art and in particular which allows easier manufacturing of devices incorporating it. A composite material, a method for producing a thin film and the electronic component thus obtained are provided.

A composite material comprising a fluoropolymer matrix; and a filler, consisting of nanoparticles of a ceramic of a BZT-αBXT type doped with at least one doping element selected from the group consisting of Nb, La, Mn, Nd and W, wherein X is selected from Ca, Sn, and Mn, and a is a molar fraction in the range between 0.10 and 0.90, provided that when X is Mn, the doping element is not Mn. A process forming a thin film including the composite material is also provided.

### BRIEF DESCRIPTION OF THE SEVERAL VIEWS OF THE DRAWINGS

For a better understanding of the present disclosure, some embodiments thereof are now described, purely by way of non-limiting example, with reference to the drawings, wherein:

FIG. 1 illustrates the X-ray diffraction (XRD) spectrum of the composite sample comprising PVDF and 25% of 2% BCNZT, i.e., (1-α)Ba(Zr_{(0.2-0.5y)}Ti_{(0.8-0.5y)})Nb_{y}O₃-αBa_{0.7}Ca_{0.3}(Ti_{(1-y)}Nb_{y})O₃, where α indicates the ratio between BZT and BCT and y=0.02 indicates the degree of substitution of Nb with respect to the sum of Titanium (Ti) and Zirconium (Zr);

FIG. 2 illustrates a cross-section through a portion of a generic MEMS device having a piezoelectric actuation structure;

FIG. 3 illustrates the results of the ferroelectric analysis conducted on a thin film made of PVDF and on a thin film formed with an undoped PVDF and BZT-BCT composite;

FIG. 4 illustrates the results of the ferroelectric analysis conducted on a thin film formed with a PVDF and 2% BCNZT composite present in quantities of 15%, 20% and 25% on the total weight of the composite;

FIG. 5 illustrates the plot of the capacitance C as a function of the frequency f in a composite material layer formed according to the present disclosure;

FIG. 6 illustrates the plot of the inductance Lp as a function of the frequency fin a composite material layer formed according to the present disclosure, for different percentages of dispersed phase load;

FIG. 7 illustrates the plot of the phase Φ as a function of the frequency f in a composite material layer formed according to the present disclosure, for different percentages of dispersed phase load;

FIG. 8 illustrates the displacement s as a function of the frequency f in a composite material layer formed according to the present disclosure;

FIG. 9 illustrates the plot of the amplitude A as a function of the frequency f in a composite material layer formed according to the present disclosure and used respectively in an ultrasonic detector (A_DUT) and in an ultrasonic microphone (A_Mic); and

FIG. 10 shows an example of device 20 using the present composite material.

### DETAILED DESCRIPTION

The present description relates to a composite material comprising a fluoropolymer matrix and a filler formed by nanoparticles of a ceramic of the BZT-αBXT type wherein X is selected from Calcium (Ca), Tin (Sn) and Manganese (Mn) and a is a molar fraction selected in the range between 0.10-0.90, including 0.10 and 0.90, doped with at least one doping element selected from the group consisting of Niobium (Nb), Lanthanum (La), Mn, Neodymium (Nd) and Tungsten (W), provided that when X is Mn, the doping element is not Mn. The nanoparticles have an average diameter comprised between 100 and 200 nm, including 100 and 200 nm.

Advantageously, the present composite material has shown improved ferroelectric and piezoelectric properties and inductive behavior.

In particular, the presence of nanoparticles favors an exchange at the matrix-nanoparticle interface. Unlike the use of fibers, which favor the stiffening of the thin film, nanoparticles allow the conductive paths essential for the inductive properties and a flexible thin film to be obtained.

In particular, the size range 100-200 nm maximizes the interface between the polymer and the filler. Average nanoparticle diameters greater than 200 nm do not guarantee an effective interface between the polymer and the ceramic for charge transfer. Instead, nanoparticles with an average diameter of less than 100 nm tend to coalesce, impeding a homogeneous distribution in the material.

The doping elements La, Mn, and Nd can replace the element in a position of the barium and calcium site while Nb and W can replace the element in a position of the titanium and zirconium site.

In one embodiment, the fluoropolymer is selected from the group consisting of polyvinylidene fluoride (PVDF) and its copolymers, in particular, copolymers of PVDF with hexafluoropropylene (HFP) or with trifluoroethylene (TrFE).

In particular, PVDF and its copolymers may have a beta-phase percentage mass fraction, with respect to the sum of the masses of the crystalline phases, of at least 70%, more particularly between 86% and 99%.

The ceramic of the BZT-αBXT type may be a ceramic of the Barium Zirconate Titanate-Barium Calcium Titanate (BZT-BCT) type, in particular a ceramic of the (1-α)Ba(Zr_{(0.2-0.5y)}Ti_{(0.8-0.5y)})Nb_{y}O₃-αBa_{0.7}Ca_{0.3}(Ti_{(1-y)}Nb_{y})O₃ type, where a indicates the ratio between BZT and BCT and y=0.01-5% by weight on the total weight of the ceramic indicates the degree of substitution of Nb with respect to the sum of Ti and Zr, in particular y=2% by weight on the total weight of the ceramic.

The composite material has a ceramic (filler) content comprised between 10% and 25% by weight on the total weight of the composite, in particular 20%. Outside this range, the properties begin to decay to a complete loss of inductive behavior. Filler percentages greater than 25% lead to an onset of coalescence phenomena, the frequency of which increases as the filler percentage increases; such coalescence phenomenon leads to an increased possibility of electrical short circuits. In contrast, a filler percentage of less than 10% results in an uneven distribution of filler within the matrix.

Hereinbelow there is described an embodiment of a process for producing a thin film formed with the composite material described above. In detail, the process comprises:
a) submitting a dispersion of ceramic nanoparticles in an organic fluoropolymer solution to a first spin-coating step over the substrate at a speed comprised between 500 and 1500 rpm, including 500 and 1500 rpm, to a second spin-coating step at a speed comprised between 3500 and 5500 rpm, including 3500 and 5500 rpm; and to a third spin-coating step at a speed comprised between 8500 and 12000 rpm, including 8500 and 12000 rpm; and
b) submitting the product of step a) to a first annealing step at a temperature comprised between 60 and 70° C., including 60 and 70° C., and to a second annealing step at a temperature comprised between 80 and 90° C., including 80 and 90° C.

Advantageously, this method allows a homogeneous and uniform thin film to be formed.

In particular, the first spin-coating step, conducted for example at 1000 rpm, leads to the application of the composite material on the entire surface of the substrate; the second spin-coating step, conducted for example at 4000 rpm, favors a first evaporation of the solvent and the third spin-coating step, conducted for example at 9000 rpm, favors the formation of the beta phase as it allows the complete stretching of the PVDF chains and the rotation of the groups H and F. In some embodiments, the substrate has a first surface opposite a second surface, the first surface of the substrate being entirely covered by the composite material.

Furthermore, the first annealing step favors a slow evaporation of the solvent which makes the surface of the thin film uniform and homogeneous; the second annealing step allows the polymer chains to consolidate after the total evaporation of the solvent.

Thanks to its ferroelectric and piezoelectric properties, the composite material may be used for manufacturing electronic components such as acoustic sensors, in particular microphones, energy harvesting transducers and micro-actuators.

Further characteristics will emerge from the following description of some merely illustrative and non-limiting examples.

### EXAMPLE 1

### Preparation of the Composite According to the Present Disclosure

### Preparation of 100 ml of 15% Weight Solution of PVDF

17.78 g of PVDF powder are dissolved in a solution of 70 ml of dimethyl sulfoxide (DMSO) and 30 ml of acetone. The solution is placed on a magnetic heated plate and stirred by magnetic stirring at a temperature of 100° C.

Preparation of Nanoparticles of BCT-BZT Doped with 2% of Nb (2% BCNZT)

The BCNZT ceramic is prepared by Sol-Gel technique as described in EP 4074672 (US 2022/0332650). The precursor solution is then dried at 150° C. and the powders are recovered.

Once recovered, the powders are homogenized and dry ground using a planetary ball mill at a speed of 400 rpm for 4 hours. They are subsequently calcined at 1400° C. and wet regrinded for 8 hours with ethanol (1 ml) to obtain nanoparticles of the order of 100-200nm.

### Preparation of the Composite

The 2% BCNZT nanoparticles are added in different amounts (15%, 20% 25% by weight on the composite weight) to the PVDF solution and are dispersed by ultrasonication and stirring. The solution is left on a plate for approximately 10 days to reach stability.

Once stabilized, the solution is deposited by spin-coating on a substrate to form a thin film. Three spin-coating steps are performed.

The method used envisages three steps:
1000 rpm per 10 s;
4000 rpm per 30 s; and
9000 rpm per 60 s.

Subsequently the sample is placed for 10 min on a plate at 70° C. for a complete evaporation and subsequently on a plate at 90° C. for another 10 min for the annealing step, finally it is cooled to room temperature T.

The films have been submitted to X-ray diffraction studies to verify the formation of the PVDF phases.

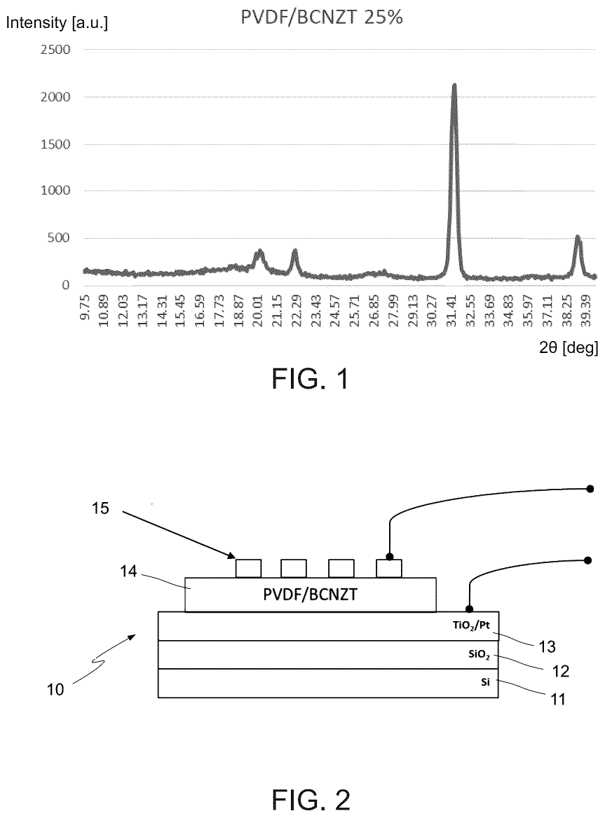

FIG. 1 shows the X-ray diffraction (XRD) spectrum of the composite sample comprising 25% of 2% BCNZT; from this it is clear that only the β-phase is present in the PVDF. The intensity of the 2% BCNZT peak also demonstrates a high homogeneity of the composite analyzed.

### EXAMPLE 2

### Electrical Characterization

For the electrical characterization, a sample 10 has been provided as shown in FIG. 2.

The sample 10 comprises a semiconductor layer 11, for example of monocrystalline silicon; an insulating layer 12, for example of silicon dioxide; a lower electrode layer 13, formed by a TiO₂/Pt multilayer; a composite layer 14 of the present PVDF-BCNZT composite material; and a plurality of upper electrodes 15 of Platinum (Pt).

In the used sample, the stack of layers 11-13 has a total thickness of 700 μm; the composite layer 14 has a thickness of 2 μm and the upper electrodes 15 have a thickness of 120 nm.

The sample is sprayed (Turbo-Pumped Thermal Evaporator K975X) with platinum to form the upper electrodes and etched at the end to contact the lower electrode. Alternatively, a sputtering process may also be used to form the upper electrodes.

For all measurements, the electrodes were contacted with metal tips through manipulators on a hand-held spindle probe. Electrical property tests and impedance spectroscopy were performed with the Keysight B1500A semiconductor device analyzer. The ferroelectric properties were studied with the Aixact TFA TF2000E analyzer, applying a 30V, 5 kHz triangular wave signal to the sample.

In particular, the samples tested are films formed with:
PVDF polymer only;
Composite comprising PVDF and BCT-BZT;
Composite comprising PVDF and 15% of 2% BCNZT;
Composite comprising PVDF and 20% of 2% BCNZT; and
Composite comprising PVDF and 25% of 2% BCNZT.

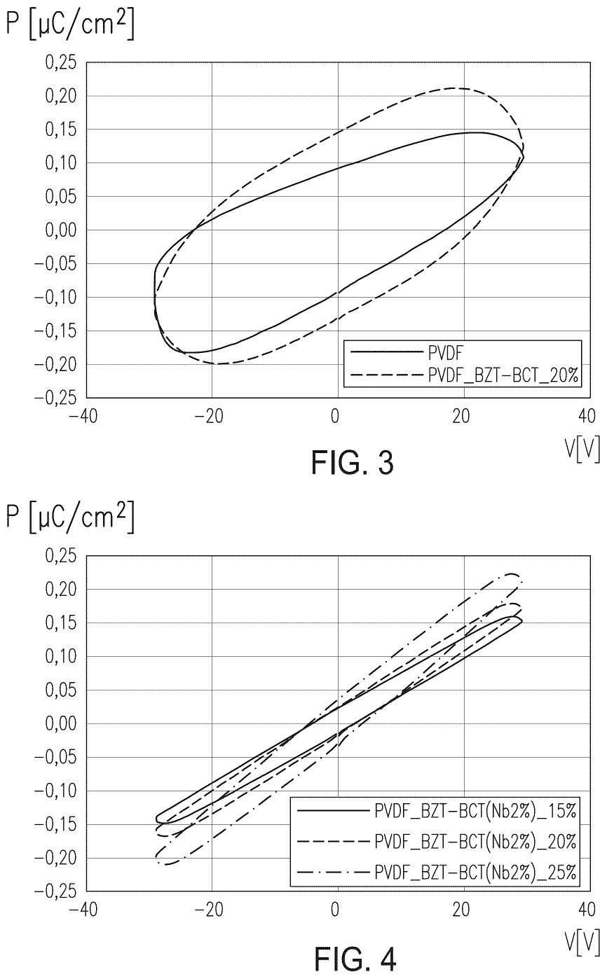

The results of the ferroelectric tests are shown in FIGS. 3 and 4.

PVDF and PVDF_BZT-BCT thin films show broader ferroelectric properties associated with inductive behavior, likely due to conductive paths emerging in the PVDF matrix.

The shape of the ferroelectric curves of FIG. 4 allows highlighting that the presence of Nb reduces the percolation path in the film which has a narrower characteristic with the same voltage.

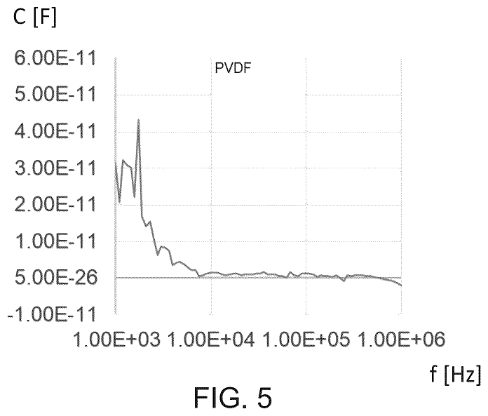

Interesting properties of Nb-doped composites emerged thanks to impedance measurements. The samples were tested with the B1530 module of the B1500A, applying a 50 mV AC signal and no DC polarization to the samples. With this module frequencies from 1 kHz to 5 MHz may be tested. These measurements confirmed the dielectric properties of the PVDF as shown in FIG. 5.

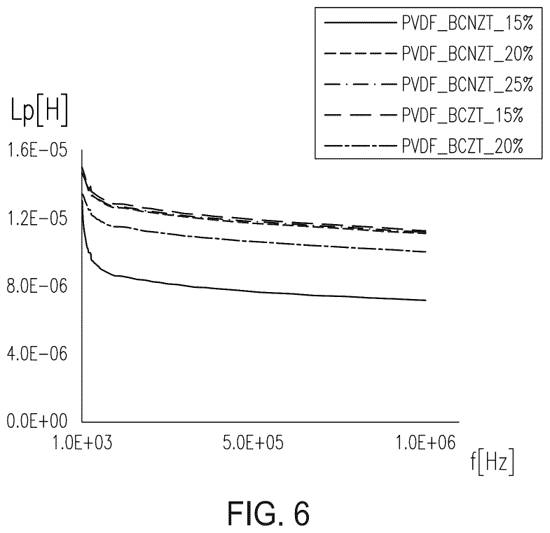

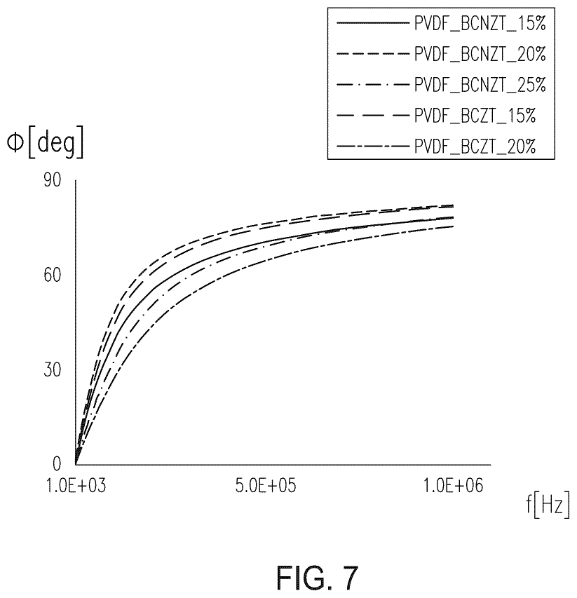

The described composites also showed an inductive nature measuring impedance and phase, as shown in FIGS. 6 and 7.

Finally, the piezoelectric properties were measured by a laser vibrometer MSA-500 Micro System Analyzer (Polytec) on a cantilever-shaped device.

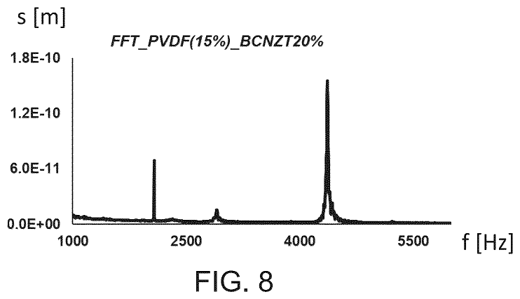

Films with different doping percentages were submitted to vibrometric testing using the MSA-500 Micro System Analyzer (Polytec) to estimate the piezoelectric parameters. In particular, the device was submitted to Fast Fourier Transform (FFT) analysis sending a periodic chirp of 3 V and the displacement was measured using a laser vibrometer. This allowed the resonance frequency to be extracted. FIG. 8 shows the plot of the displacement as a function of the frequency presented by a device having a layer of the composite material containing PVDF and 20% of 2% BCNZT.

Once the resonance frequency was extracted, by setting voltage and frequency in proximity to the resonance, the deflection of the cantilever was estimated. The displacement and the corresponding value of the effective in-plane transverse piezoelectric coefficient e31f were shown in Table 1 according to the formula proposed by Mazzalai:

$${e}_{31 , f} = \frac{1}{3 V} \frac{{Y ( {t}_{Si} )}^{2}}{3 V ( 1 - v ) {c}_{f}} \frac{w ( {x}_{2} )}{[ 2 {x}_{2} - {x}_{1} ] {x}_{1}}$$

where Y is the Young's modulus, v is the Poisson's ratio, t_{Si} is the thickness of the substrate (in the sample of FIG. 2, the semiconductor layer 11-13), c_{f} is the coverage factor of the electrodes, x₂ is the length of the piezoelectric active area, x₁ is the length of the laser impingement point, w(x₂) is the deflection, V is the amplitude of the sinusoidal signal applied.

TABLE 1

| | | | | Piezoelectric |
|---|---|---|---|---|
| Content [%] | | | Displacement | Coefficient |
| PVDF | BZTBCT | Nb | w(x₂) [m] | e_{31, f} [C/m2] |
| 15 | 15 | 0 | 2.00e−9 | 0.672 |
| 15 | 20 | 0 | 3.30e−9 | 1.109 |
| 15 | 15 | 2 | 4.25e−9 | 1.785 |
| 15 | 20 | 2 | 9.00e−9 | 3.781 |
| 15 | 25 | 2 | 2.70e−9 | 1.134 |

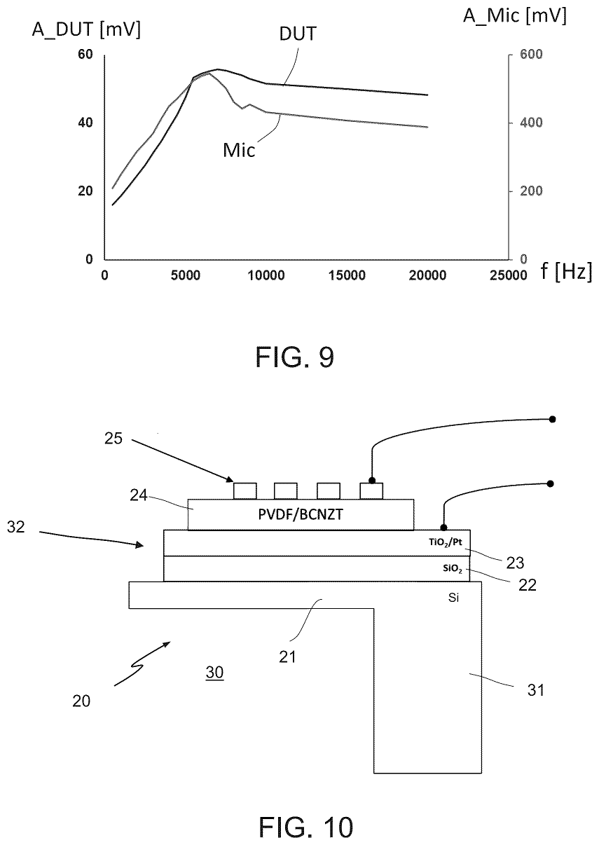

Furthermore, since a resonance frequency close to 4 kHz was detected, the behavior of various devices exposed to sound pressure was studied. The acoustic wave is sent from a speaker to the cantilever and with the Micro System Analyzer MSA-500 the response of a device comprising the described composite material of a certified commercial microphone was studied. The measurement was carried out by driving the speaker with an external sinusoidal signal at various frequencies of the audible range, from 20 Hz to 20 kHz. It has been found that the response of the device comprising the composite material comprising PVDF and 20% of 2% BCNZT follows the signal detected by the microphone, with an amplitude that differs by one tenth from the certified microphone, as shown in FIG. 9, wherein A_Mic refers to the amplitude measured in the certified commercial microphone and A_DUT refers to the cantilever device using the present composite material.

FIG. 10 shows an example of device 20 using the present composite material.

The device 20 is for example a MEMS sensor or actuator; in particular a microphone.

The device 20 has a suspended structure 21, here a cantilever, suspended over a cavity 30.

The cavity 30 is formed in a substrate 31 and delimits the suspended structure 21 at the bottom. The suspended structure 21 may be monolithic with the substrate 31. The suspended structure 21 and the fixed structure 31 are for example of monocrystalline silicon.

An insulating layer 22, for example of silicon dioxide, extends above the suspended structure 21 and an actuation or detection structure 32 extends on the insulating layer 22.

The actuation or detection structure 32 comprises a lower electrode layer 23, for example formed by a TiO₂/Pt multilayer; a composite layer 24, of the present PVDF_2% BCNZT composite material; and a plurality of upper electrodes 25, for example of Pt.

Finally, it is clear that modifications and variations may be made to the composite material and the production process described and illustrated herein, without departing from the scope of the present disclosure, as defined in the claims.

A composite material comprising a fluoropolymer matrix and a filler consisting of nanoparticles of a ceramic of the BZT-αBXT type wherein X is selected from Ca, Sn, and Mn, and a is a molar fraction selected in the range between 0.10 and 0.90, including 0.10 and 0.90, doped with at least one doping element selected from the group consisting of Nb, La, Mn, Nd and W, wherein when X is Mn, the doping element is not Mn. Said differently, in some embodiments, when X is Mn, the doping element is selected from the group consisting of Nb, La, Nd, and W.

Said nanoparticles have an average diameter comprised between 100 and 200 nm, including 100 and 200 nm.

The fluoropolymer is selected from the group consisting of polyvinylidene fluoride (PVDF) and its copolymers.

The copolymers are selected from the group consisting of copolymers of PVDF with hexafluoropropylene (HFP) or copolymers of PVDF with trifluoroethylene (TrFE).

The polyvinylidene fluoride (PVDF) and its copolymers have a beta-phase percentage mass fraction, with respect to the sum of the masses of the crystalline phases, of at least 70%.

The polyvinylidene fluoride (PVDF) and its copolymers have a beta-phase percentage mass fraction, with respect to the sum of the masses of the crystalline phases, comprised between 86% and 99%, including 86% and 99%.

The doping element is present in an amount comprised between 0.01% and 5%, including 0.01% and 5%, by weight on the total weight of the ceramic.

The composite material a ceramic content comprised between 1% and 70%, including 1% and 70%, by weight on the total weight of the composite.

A process for producing a thin film comprising the composite material, including the steps of: a) submitting a dispersion of nanoparticles in an organic-phase fluoropolymer solution on the substrate to a first spin-coating step at a speed comprised between 500 and 1500 rpm, including 500 and 1500 rpm; to a second spin-coating step at a speed comprised between 3500 and 5500 rpm, including 3500 and 5500 rpm; and to a third spin-coating step at a speed comprised between 8500 and 12000 rpm, including 8500 and 1200 rpm; and b) submitting the product of step a) to a first annealing step at a temperature comprised between 60 and 70° C., including 60 and 70° C., and to a second annealing step at a temperature comprised between 80 and 90° C., including 80 and 90° C.; wherein the nanoparticles are nanoparticles of a ceramic of the BZT-αBXT type wherein X is selected from Ca, Sn, and Mn, and a is a molar fraction selected in the range between 0.10-0.90 doped with at least one doping element selected from the group consisting of Nb, La, Mn, Nd and W. In some embodiments, when X is Mn, the doping element is selected from the group consisting of Nb, La, Nd, and W.

An electronic component comprising a piezoelectric layer including said composite material.

The electronic component forming an acoustic sensor.

The acoustic sensor is a microphone.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A composite material comprising:
a fluoropolymer matrix; and
a filler, consisting of nanoparticles of a ceramic of a BZT-αBXT type doped with at least one doping element selected from the group consisting of Nb, La, Mn, Nd and W, wherein X is selected from Ca, Sn, and Mn, wherein when X is Mn, the doping element is not Mn, and a is a molar fraction in the range between 0.10 and 0.90, wherein the nanoparticles have an average diameter between 100 and 200 nm and wherein the filler is present in an amount comprised between 10 and 25% by weight on the total weight of the composite.

2. The composite material according to claim 1, wherein the fluoropolymer matrix is selected from the group consisting of polyvinylidene fluoride (PVDF) and its copolymers.

3. The composite material according to claim 2, wherein the copolymers are selected from the group consisting of copolymers of PVDF with hexafluoropropylene (HFP) or copolymers of PVDF with trifluoroethylene (TrFE).

4. The composite material according to claim 2, wherein the polyvinylidene fluoride (PVDF) and its copolymers have a beta-phase percentage mass fraction, with respect to the sum of the masses of the crystalline phases, of at least 70%.

5. The composite material according to claim 4, wherein the polyvinylidene fluoride (PVDF) and its copolymers have a beta-phase percentage mass fraction, with respect to the sum of the masses of the crystalline phases, between 86% and 99%.

6. The composite material according to claim 1, wherein the doping element is present in an amount between 0.01% and 5% by weight on the total weight of the ceramic.

7. The composite material according to claim 1, comprising a ceramic content of 20% by weight on the total weight of the composite.

8. A process, comprising:
forming a thin film including a composite material having a fluoropolymer matrix and a filler, the filler including nanoparticles of a ceramic of a BZT-αBXT type doped with at least one doping element selected from the group consisting of Nb, La, Mn, Nd and W, wherein X is selected from Ca, Sn, and Mn, and a is a molar fraction in the range between 0.10 and 0.90, and wherein when X is Mn, the doping element is not Mn.

9. The process of claim 8, wherein producing the thin film includes submitting a dispersion of nanoparticles in an organic-phase fluoropolymer solution to a first spin-coating step, a second spin-coating step, and a third spin-coating step.

10. The process of claim 9, wherein:
the first spin-coating step is at a speed between 500 and 1500 rpm;
the second spin-coating step is at a speed between 3500 rpm and 5500 rpm; and
the third spin-coating step is at a speed between 8500 rpm and 12000 rpm.

11. The process of claim 9, further comprising, after the third spin-coating step, a first annealing step at a temperature between 60 and 70° C.

12. The process of claim 11, further comprising, after the first annealing step, a second annealing step at a temperature between 80 and 90° C.

13. An electronic component comprising a piezoelectric layer including the composite material according to claim 1.

14. A device, comprising:
a substrate having a first surface opposite a second surface; and
a layer of piezoelectric material entirely covering the first surface of the substrate, the piezoelectric material including a fluoropolymer matrix, ceramic nanoparticles, and at least one doping element of Nb, La, Mn, Nd, and W, the ceramic nanoparticles are of a BZT-αBXT type,
wherein:
X is selected from Ca, Sn, and Mn;
the doping element and X are different; and
α is a molar fraction in a range between 0.10 and 0.90.

15. The device of claim 14, wherein when X is Mn, the doping element is not Mn.

16. The device of claim 14, wherein the ceramic nanoparticles are 2% by weight the doping element.

17. The device of claim 14, wherein the piezoelectric material is 15% by weight the fluoropolymer matrix.

18. The device of claim 17, wherein the piezoelectric material ranges from 15% to 25% by weight of the ceramic nanoparticles.

19. The device of claim 18, wherein the piezoelectric material is 20% by weight of the ceramic nanoparticles.

20. The device of claim 14, wherein the layer of piezoelectric material has a thickness of 2 μm, the thickness being in a first direction from the layer of piezoelectric material to the substrate.
